(19) United States
(12) Patent Application Publication
(10) Pub. No.: US 2026/0311736 A1
(43) Pub. Date: Oct. 8, 2026

(54) Electronic Device and Methods for Assigning Bits to Memristive Devices

(71) Applicant: Telefonaktiebolaget LM Ericsson (publ), Stockholm (SE)

(72) Inventors: Mojtaba Mahdavi, Lund (SE); Saeed Bastani, Dalby (SE)

(21) Appl. No.: 19/481,345

(22) PCT Filed: Jun. 2, 2023
(86) PCT No.: PCT/EP2023/064786

§ 371 Date: Nov. 4, 2025

(51) Int. Cl. G11C 11/40

(52) U.S. Cl. CPC G11C 11/40

(57) ABSTRACT

A method, performed by an electronic device for assigning a number of bits of a binary representation of a value to two or more memristive devices of a crossbar array comprising a plurality of memristive devices. The number of bits to be assigned is larger than a number of the two or more memristive devices. The method comprises obtaining (1402) an assigning priority of each bit of the binary representation binary representation of the value. For an unassigned memristive device of the two or more memristive devices the method further comprises assigning (1407) an unassigned bit of the number of bits to the unassigned memristive device based on: the assigning priority of the unassigned bit, number of remaining unassigned memristive devices after the assignment of the unassigned bit and number of remaining unassigned slices of one or more consecutive unassigned bits after the assignment of the unassigned bit.

### TECHNICAL FIELD

The embodiments herein relate to an electronic device and methods for assigning bits to memristive devices. A corresponding computer program and a computer program carrier are also disclosed.

### BACKGROUND

Analog memristive devices have emerged as a new technology for storing and processing information in analog domain. These devices make it possible to perform computations in a place where data is stored. This concept is called in-memory computing, which eliminates the need for moving data from a memory to a processing unit.

There are different types of memristive devices, which are differentiated with respect to the used materials, switching principles, device endurance, retention, etc. Types of memristive devices include phase change memory (PCM), resistive random-access memory (ReRAM), spin-transfer torque magnetic RAM (STT-MRAM), ferroelectric memristive devices (FeRAM).

A large number of memristor devices may be organized to form analog crossbar arrays (CBA). CBA, as a key building block of memristor-based hardware architecture, may enable massive multiplication-accumulations (MACs) in parallel. For example, convolutional layers of a neural network may be mapped to one or more CBAs interconnected to one another to accelerate the processing of the neural network.

FIG. 1 illustrates a memristor-based electronic device 100 comprising a memristor crossbar array 110 which computes matrix-vector multiplication (MVM) by calculating a dot-product of the input vector applied to crossbar rows (i.e., word lines) and every column of the crossbar (i.e., bit lines). This may be performed in analog domain using Ohm's law for multiplication and Kirchhoff's law for accumulation.

The memristor crossbar array 110 is a two-dimensional array that comprises an M×M array of memristors 111, 112, 121, 122, each of which may be programmed to represent an m-bit binary value. A memristor is a tunable resistor with memory. The memristor may comprise a dielectric layer sandwiched by two electrodes. A unique feature of memristors is that the conductance depends on historical electrical signals, making them capable of working as nonvolatile memory. In addition, memristors may store multibit information with tunable conductance, in contrast to binary states “0” and “1” in traditional digital storage systems, equipping them with higher bit density. Thus, the m-bit binary value of the memristor may be set or programmed by applying a current to the memristor. The binary value may depend on the amplitude of the current. Thus, an M×M matrix of binary words, G, may be represented by the memristor crossbar array 110 comprising M×M memristors. The input to the memristor crossbar array 110 is an electronic input signal of multiple samples, such as a vector of M binary values, e.g., V.

Analog crossbar arrays are usually accompanied with additional peripheries such as data converters, i.e., analog to digital converters (ADC) and digital to analog converter (DAC) to interface with digital domain, and to perform some operations such as shift and add, pooling, and non-linarites (e.g., sigmoid and ReLU functions). The accumulated current on each bit line of the crossbar is separately converted to a digital value. However, multiple bit lines may share one ADC in a time-multiplexed fashion and hence reduce ADC overhead. The supported bit resolution of ADC determines the quantization error; the higher the supported bit resolution the lower the quantization error.

Memristive devices have inherent non-idealities, including different sources of noise, such as thermal and programming noise, and variations, such as device to device and cycle to cycle variations, conductance drift, limited endurance and retention.

Due to various sources of non-idealities, memristive devices of today support limited bit precision, attributed to the limited number of conductance levels that may be reliably programmed in the device. For example, a PCM device may support around 50 conductance levels, meaning that it may represent around 6 bits. There are also devices which operate in binary mode (1 bit precision). A memristive device with a nominal bit precision N should allow programming of up to 2^{N} distinct conductance levels within the dynamic range of the device characterized by [G_off, G_on], where G_off and G_on are the minimum and maximum conductance levels supported by the memristive device. Due to the different noise sources (notably, thermal and programming noise), the consecutive conductance levels programmed in the device must be well separated with high confidence. FIG. 2 illustrates normally distributed memristive conductance due to noise effects. The larger the ΔG, the more robust to noise is an algorithm using the crossbar for computations. So, the smaller the N, the better the separation is between consecutive conductance level and hence the more robustness to noise effects will be achieved in an algorithm that runs on the memristive devices.

Different applications require different bit-precision for representing algorithmic parameters, such as weight parameters in neural networks, in order to meet an expected accuracy to be achieved by the application. For example, with an increase of an expected classification accuracy in an image classification application, a higher bit precision is required for representing the parameters of the classification algorithm.

A common solution to bit precision deficit of a memristor device is the use of multiple memristive devices to represent a single parameter of the algorithm. For example, if an algorithm parameter requires 16-bit precision but a single device supports only 2-bit precision, 8 such devices are consolidated within a row of a crossbar or spread across multiple crossbar arrays to program the 16-bit parameter. This process is called synaptic bit-slicing—a synapse is a term from the context of biological brain. In an Artificial Intelligence domain, it corresponds to the weight of a connection between two neurons in a neural network algorithm. When implementing a neural network using crossbar arrays, each cell of the crossbar, e.g., each memristor, represents a synapse, connecting the input (neuron) to an output (neuron). In the following sections, the terms “algorithm parameter”, “weight” and “weight parameter” will be used interchangeably.

Existing solutions for synaptic bit-slicing in memristive crossbar arrays are mainly based on homogeneous bit slicing. For example, eight memristive devices may be allocated, each with 2-bit precision, to represent a weight value that requires 16-bit precision. In another example, two devices each with 4-bit precision are allocated to represent a weight value that requires 8-bit precision.

Taking the first example, a 16-bit weight value (b₁₅b₁₄b₁₃b₁₂ . . . b₁b₀) is split across eight memristive devices (d₇d₆ . . . d₀), where b₁₅b₁₄ is programmed in d₇, b₁₃b₁₂ is programmed in d₆ and so on so forth. In a homogeneous bit-slicing scheme, a number of devices n=ceil(m/p) are allocated to each weight value where m is the number of bits per weight and p is the bit precision supported by a single memristive device.

For cases where device budget is limited, for example, when a size of an algorithm is big and or hardware resources are limited, the number of devices may be smaller than ceil(m/p). If, for instance, m is 8 bits and device budget is 3 devices, each supporting 2 bits precision, a homogeneous solution cannot allocate those 3 devices, supporting 6 bits precision in total, to map a weight value with 8-bit precision. A trivial solution is to reduce the bit precision of the weight parameter to 6 bits, but it may have negative effects on the accuracy of the algorithm.

Another solution to achieve a high accuracy may be to increase the number of devices per parameter without considering the hardware limitation such as hardware cost, power/energy consumption, etc. In other words, the number of devices per parameter is dictated by a certain method and it is not under a control of a designer of crossbar arrays.

In general, there are some challenges regarding mapping (bit assignment) the weights values to the available memristive devices. For example, how many bits should be assigned to each memristive device such that a device budget is efficiently utilized for any values of n and m?

### SUMMARY

An object of embodiments herein may be to obviate some of the problems related to assigning bits to memristive devices, such as in bit-slicing.

Another issue with homogeneous bit-slicing is that different bit positions of the weight parameter are treated indifferently, e.g. the same number of devices are allocated to most significant bits (MSBs) as they are allocated to least significant bits (LSBs). This device allocation scheme does not utilize hardware resources, such as memristor devices, in an optimal fashion so as to preserve and possibly enhance the algorithm accuracy without imposing additional hardware resources.

In a prior art reference solution an “importance” of a bit is always specified by its position in the corresponding binary word, meaning that the MSB is always considered as the most important bit and the LSB as the least important bit. In the prior art solution the MSB is always protected, i.e., exclusively assigned to a memristive device, while the other bits are not, for a case where there are fewer memristive devices than bit positions. However, for many applications other bit positions than MSB may be defined as the most important. Depending on the use case, the important bit may be in any bit position such that the most important bit may even be the LSB, i.e. the bit in position 0. Thus, having considered that the sensitivity level of each bit-position is known, e.g. by means of some analysis, how should an allocation of memristive devices to different bit-positions be prioritized with respect to the available device budget? How many and which bit-positions should be assigned to a certain memristive device?

The prior art solution described above does not guarantee that all bit parameters can be mapped to a memristive-based array with a certain number of memristive devices.

Further, there are many parameter configurations (i.e., number of devices and bits per weight), which are not supported by this prior art solution. Examples are:
Device budget=3 and Number of bits per parameter=7
Device budget=5 and Number of bits per parameter=7

Further, it is a natural case that the weights may change over the time, including the change in the number of required bits to represent the weights, the sensitivity score of each bit, and the positions of bits with highest scores. Therefore, it is needed to update the weights, meaning that the memristive devices should be reprogrammed. Thus, it may be needed to rearrange the bit assignment and find the efficient pattern according to the updated weights.

Embodiments herein introduce a method of heterogeneous bit slicing for allocating memristive devices to store bits, such as for algorithm parameters.

According to an aspect of embodiments herein, the object is achieved by a method, performed by an electronic device for assigning a number of bits of a binary representation of a value to two or more memristive devices of a crossbar array comprising a plurality of memristive devices. A number of bits to be assigned is larger than a number of the two or more memristive devices. That is, there is a plurality of bits.

The method comprises obtaining an assigning priority of each bit of the binary representation of the value.

For an unassigned memristive device of the two or more memristive devices the method further comprises assigning an unassigned bit of the number of bits to the unassigned memristive device based on: the assigning priority of the unassigned bit, a number of remaining unassigned memristive devices after the assignment of the unassigned bit and a number of remaining unassigned slices of one or more consecutive unassigned bits after the assignment of the unassigned bit.

According to a second aspect of embodiments herein, the object is achieved by an electronic device configured to assign a number of bits of a binary representation of a value to two or more memristive devices of a crossbar array comprising a plurality of memristive devices. A number of bits to be assigned is larger than a number of the two or more memristive devices. The electronic device is configured to obtain an assigning priority of each bit of the binary representation of the value.

The electronic device is further configured to, for an unassigned memristive device of the two or more memristive devices, assign an unassigned bit of the number of bits to the unassigned memristive device based on: the assigning priority of the unassigned bit, a number of remaining unassigned memristive devices after the assignment of the unassigned bit and a number of remaining unassigned slices of one or more consecutive unassigned bits after the assignment of the unassigned bit.

According to a further aspect, the object is achieved by computer program, comprising computer readable code units which when executed on a processor of an electronic device causes the electronic device to perform the method according to the first aspect above.

According to a further aspect, the object is achieved by a carrier comprising the computer program of the aspect above, wherein the carrier is one of an electronic signal, an optical signal, an electromagnetic signal, a magnetic signal, an electric signal, a radio signal, a microwave signal, or a computer-readable storage medium.

Since the unassigned bit is assigned to the unassigned memristive device based on the assigning priority of the unassigned bit, the number of remaining unassigned memristive devices after the assignment of the unassigned bit and the number of the remaining unassigned slices after the assignment of the unassigned bit, a maximum number of bits, which have the highest sensitivity level, is protected, i.e., exclusively assigned to a memristive device.

Bits with higher assigning priority are prioritized over bits with lower assigning priority. The number of protected bits is optimized since the number of remaining unassigned memristive devices after the assignment of the unassigned bit and the number of the remaining unassigned slices after the assignment of the unassigned bit is taken into account. That is, a relative position of the unassigned bit to be assigned and the already assigned bits, such as the high sensitivity bits, is taken into account.

The number of remaining unassigned memristive devices after the assignment of the unassigned bit is dependent on the original device budget. The number of the remaining unassigned slices is dependent on the original number of bits and the relative position of the already assigned bits.

Thus, given an arbitrary device budget and weights, embodiments herein finds an efficient mapping pattern of the weights to the memristive devices such that a maximum number of bits, which have the highest sensitivity level, may be protected.

### BRIEF DESCRIPTION OF THE DRAWINGS

In the figures, features that appear in some embodiments are indicated by dashed lines.

The various aspects of embodiments disclosed herein, including particular features and advantages thereof, will be readily understood from the following detailed description and the accompanying drawings, in which:

FIG. 1 is a block diagram schematically illustrating an electronic device comprising a memristor crossbar array,

FIG. 2 is a graph illustrating normally distributed memristive conductance,

FIG. 3 is a system block diagram schematically illustrating an electronic device according to embodiments herein,

FIG. 4 is a block diagram schematically illustrating a method according to some embodiments herein,

FIG. 5 is a block diagram schematically illustrating a further method according to some further embodiments herein,

FIG. 6 is a flowchart illustrating embodiments of a method for assigning a number of bits to two or more memristive devices,

FIG. 7(a) is a block diagram illustrating embodiments of a method for assigning a number of bits to two or more memristive devices,

FIG. 7(b) is a block diagram illustrating embodiments of a method for assigning a number of bits to two or more memristive devices,

FIG. 7(c) is a block diagram illustrating embodiments of a method for assigning a number of bits to two or more memristive devices,

FIG. 8 is a block diagram illustrating further embodiments of a method for assigning a number of bits to two or more memristive devices,

FIG. 9 is a block diagram illustrating yet further embodiments of a method for assigning a number of bits to two or more memristive devices,

FIG. 10 is a block diagram illustrating yet further embodiments of a method for assigning a number of bits to two or more memristive devices,

FIG. 11 is a block diagram illustrating a scenario in which embodiments herein may be employed,

FIG. 12 is a block diagram illustrating yet further embodiments of a method for assigning a number of bits to two or more memristive devices,

FIG. 13 is a block diagram illustrating a constellation diagram,

FIG. 14 is a flowchart illustrating embodiments of a method for assigning a number of bits to two or more memristive devices,

FIG. 15 is a further flowchart illustrating an implementation of embodiments herein,

FIG. 16 is yet a further flowchart illustrating embodiments of a method for assigning a number of bits to two or more memristive devices,

FIG. 17 is a schematic block diagram illustrating embodiments of an electronic device.

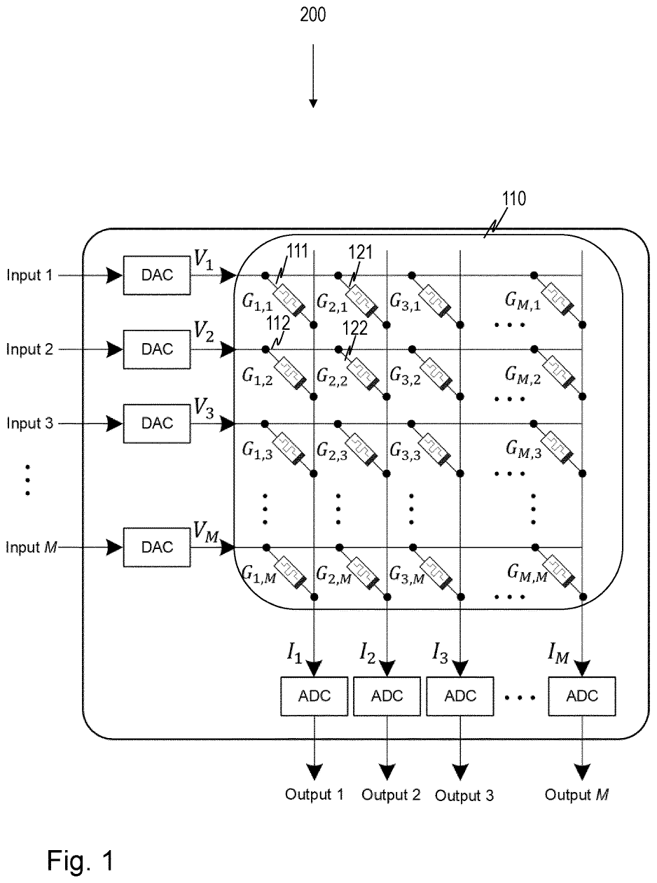

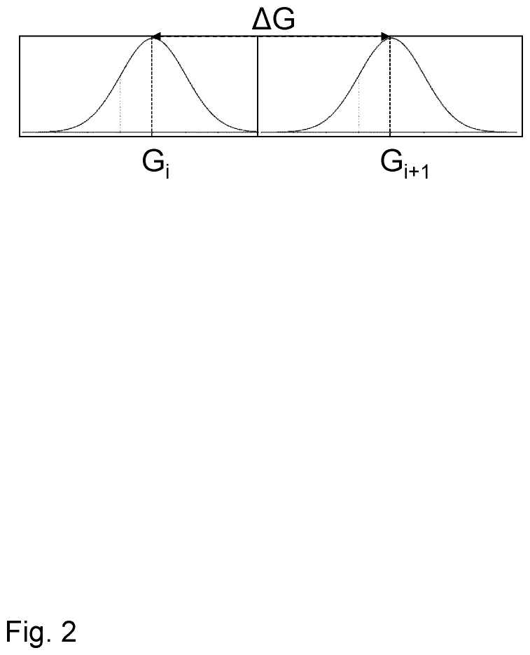

### DETAILED DESCRIPTION

As mentioned above, there are challenges and issues with how to map bits to memristive devices. An object of embodiments herein is therefore to improve methods for mapping bits to memristive devices. Embodiments herein provide mechanisms for heterogenous bit slicing.

Numerical values, such as values of algorithm parameters, may be organized in a matrix form, e.g., corresponding to weights in a convolution or fully connected layer of a neuronal network algorithm. Denote a weight matrix, W, with size of N×M, where an entry of W is denoted by wᵢⱼ. A vector wⱼ represents all weight values w in a j^{th} column of W. Assume a required bit precision for each weight w is m bits. Hence, the binary representation of a weight w is [bₘ₋₁bₘ₋₂ . . . b₁b₀], and binary representation of a vector wⱼ is denoted by [b^{j}ₘ₋₁b^{j}ₘ₋₂ . . . b^{j}₁b^{j}₀] (note that b^{j}ₖ is a vector that represents the bit value in k-th position of all individual weights w in wⱼ). A score function fₛ may be used to determine an importance, or in other words a sensitivity, of every bit position k in wⱼ with respect to the impact of the bit position on an algorithm accuracy.

A size of a memristive crossbar array may be denoted by R rows by C columns. Each entry of the crossbar comprises one memristive device. The maximum bit-precision offered by a single memristive device is p. The device budget per weight parameter, i.e., the number of memristive devices to be allocated to each weight value w, is n. In the most convenient case, n=ceil(m/p) but, in a more general sense, n<=m. Embodiments herein address the general case where n<=m.

With the above assumptions, embodiments herein map matrix W to the crossbar array. Note that, depending on the matrix size compared to crossbar size, matrix W may be mapped to multiple crossbar arrays or may occupy a fraction of a crossbar array. However, for the sake of simplicity, we assume W fits a single crossbar array. That is, the number of crossbar columns C>=M×n (M multiplied by n) and the number of crossbar rows R>=N. However, embodiments herein are independent of the matrix and crossbar sizes.

To map matrix W to a crossbar array, each column of W is treated independently. For each column vector wⱼ in W and given device budget of n devices per weight w in wⱼ and bit precision m required per weight w, the proposed heterogeneous bit slicing solution determines the mapping of bits [b^{j}ₘ₋₁b^{j}ₘ₋₂ . . . b^{j}₁b^{j}₀] of vector wⱼ to n columns of the crossbar array. The outline of the solution is as follows:
a) Determine the number of bits (m) required for the numerical representation of each algorithm parameter. This action may be performed in a software domain, using optimization techniques such as quantization. Optimal bit precision m may correspond to minimum bit precision needed to represent algorithm parameters without affecting algorithm accuracy considerably compared to floating point precision.
b) For each weight vector wⱼ of the j^{th} column of matrix W,
   I. If n=1, the whole m bits of each weight will be assigned to a single memristive device. Therefore, one crossbar column is assigned wⱼ
   II. If n=m, then assign one column of crossbar array to each bit position in wⱼ
   III. If 1<n<m, calculate a score value (sensitivity value) for the set of bits b^{j}ₖ in each bit position k (k=0, 1, 2, . . . , m−1) of weight vector wⱼ. This gives m score values, i.e., one per bit position. Then, crossbar columns are allocated based on the order of priority with respect to bit positions with highest score, second highest score and so on so forth, until there is only one crossbar column out of n crossbar columns is left to be assigned to wⱼ. This last crossbar column is allocated to all other bit positions k not being allocated so far.

Note: an example scoring scheme may be as simple as assigning score values based on bit position, e.g. high scores for MSBs and low scores for LSBs. However, in some other embodiments herein the LSB may be the most sensitive bit with the highest score. Another scoring scheme may be the toggle rate of all bits b^{j}ₖ in position k. See Section below for a detailed description of this embodiment. Other type of score values may be based on information entropy of the set of bits b^{j}ₖ. The scoring scheme may, among other factors, take into account application/algorithm aspects, such as how sensitive a performance of the algorithm is with respect to bit position.

In embodiments herein multiple bits may be protected, e.g., each protected bit may be exclusively assigned to a memristive device. Further, the bits are assigned according to their sensitivity level and the number of memristive devices per parameter, i.e., a device budget.

Embodiments herein guarantee that all bits are assigned to memristive devices for an arbitrary device budget and an arbitrary number of bits per parameter while the performance is improved with respect to prior art methods for assigning bits.

Embodiments herein achieve a better accuracy for a given fixed device budget.

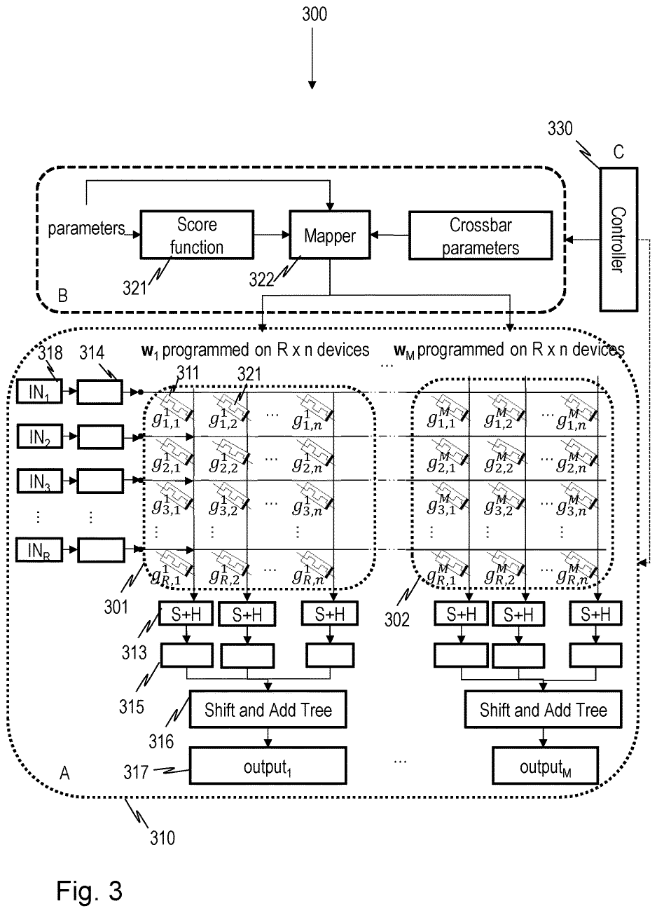

FIG. 3 depicts a system block diagram, grouped in three blocks, of an electronic device 300 according to embodiments herein.

Block A: represents a memristive hardware unit 310, comprising crossbar array(s) 301, 302 and peripheral circuitry for converting current to voltage (sample and hold circuitry 313), converting data (digital to analog converters 314 and analog to digital converters 315), and shift & adders 316 for accumulating partial sums obtained from different columns (aka. bit lines) of the crossbar array.

The crossbar array(s) 301, 302 comprises a plurality of memristive devices 311, 321.

The accumulated results may be stored in an output memory 317 (e.g. register). The inputs to the crossbar rows (aka. word lines) may be read from an input buffer 318 (e.g. SRAM) or from an off-chip memory (not shown in the figure). Note that a memristive hardware unit may comprise multiple crossbar arrays, and multiple memristive hardware units may be fabricated in a chip and interconnected with one another (not shown in the figure).

Block B: represents modules described by embodiments herein. Algorithm parameters (e.g. weight matrix W) may be fed to a score function module 321 to determine the score per bit position in each column vector of the parameters matrix. The score values, crossbar parameters and algorithm parameters may be used in a mapper module 322 to map the bit positions of each matrix column onto the crossbar bit lines. Each matrix column wⱼ spans n columns of the crossbar array where n is a pre-determined device budget. The mapper module 322 performs this task for every column wⱼ of the matrix W. Note that matrix W may span multiple crossbar arrays (for example due to large number of rows or columns or both). For the simplicity of illustrations, the block diagram in FIG. 3 comprises only one crossbar array that accommodates the matrix W. However, embodiments herein may be applied to any matrix sizes and any crossbar array settings, such as any number of bit lines and word lines.

Block C: represents a controller module 330. The controller module 330 is responsible for synchronizing different components in the memristive hardware unit 310 (reading input, data conversion, writing to output buffer, etc.). The controller module 330 is also responsible for the reconfiguration of shift & add trees, depending on how the matrix has been mapped to the crossbar array 301, 302. Another task of the controller is to activate the modules in block B when a new set of algorithm parameters arrive at the system and need to be scored and mapped to the crossbar array 301, 302.

### Inputs of the Crossbar Array

In the proposed scheme, the input to the crossbar array 301, 302 may be fed either in a bit-serial manner (i.e., bit by bit), or in slices of two or more bits, or a whole word at once. The bit assignment and specifying the most sensitive bits is independent of the input pattern.

### Outputs of the Crossbar Array

The output current of crossbar columns is converted to voltages, using e.g., the sample and hold circuitry 313 or a TransImpedence Amplifier, and then converted to corresponding binary numbers by means of the ADC 315. Finally, a reconfigurable tree of shift and adder modules 316 may be used to generate the result of matrix vector multiplication. Note that, while the memristive devices are reprogrammed, the shift and add tree may be reconfigured as well. This may be done in the controller module 330. The configuration of this tree of shift and adder modules 316 may be done by considering a pattern of bit-assignment and a position of protected bits, which may be provided by a mapping algorithm of the mapper module 322.

### Sensitivity Score Function

The score function module 321 may assign scores to different bits in the binary representation of the parameter before mapping to the crossbar array 301, 302. The score value may determine the sensitivity of the algorithm accuracy to individual bits in the binary representation of the parameter. Two examples of different score functions will now be given to describe how the heterogeneous bit slicing and mapping solution benefit from score values obtained from a score function.

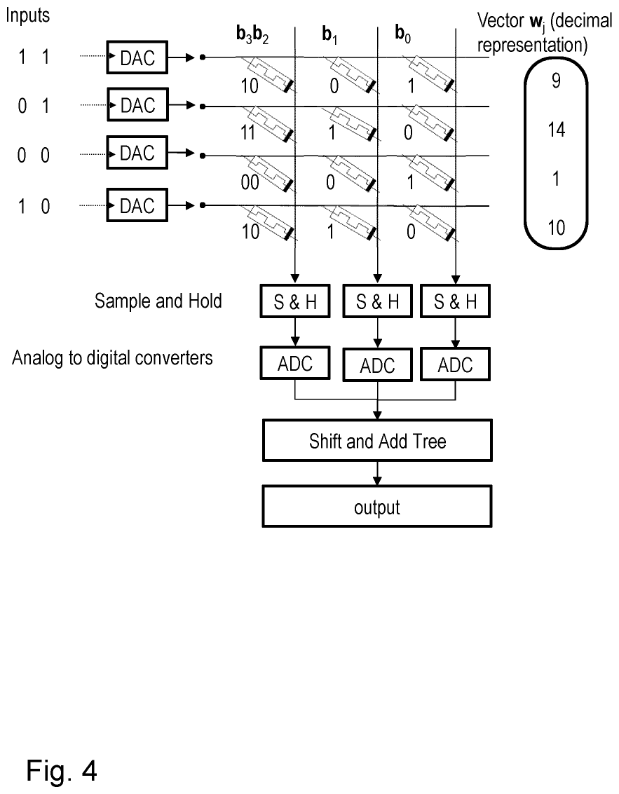

FIG. 4 shows a mapping of a weight vector wⱼ based on heterogenous bit slicing and using bit toggle rate (i.e., representing number of changing bit values from 0 to 1 and 1 to 0) as sensitivity score. Given device budget per weight value is n=3 memristive devices (hence there are 3 crossbar columns per weight vector wⱼ). Required bit precision per weight value is m=4 bits since the highest value of the weights is 14. Toggle rate is used to score each bit position. In the above example, b₁ and b₀ have the highest scores (each with score 3, representing number of changing bit values from 0 to 1 and 1 to 0). Hence, one crossbar column is dedicated to b₁ (each row of such crossbar column is assigned to a corresponding bit in vector b₁), another crossbar column is allocated to b₀, and one remaining crossbar column is allocated to all other bits with low scores (i.e., b₃b₂).

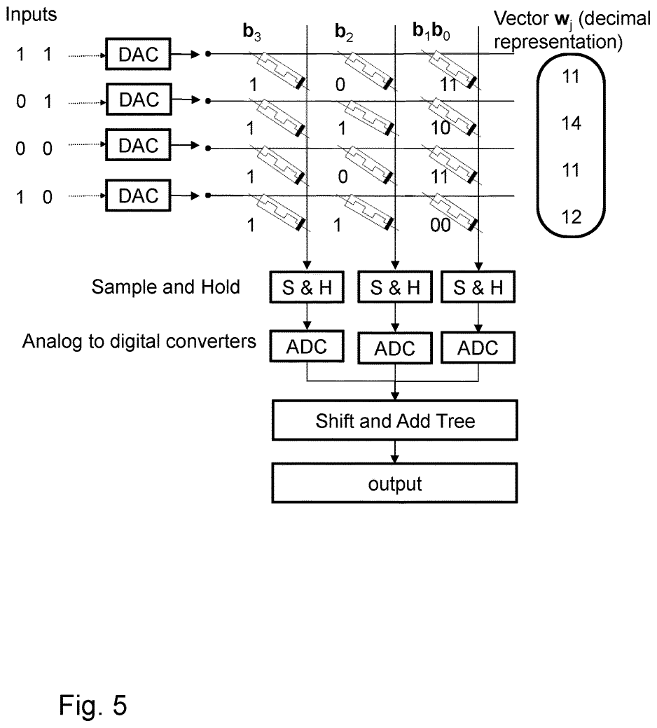

FIG. 5 shows mapping of a weight vector wⱼ based on heterogenous bit slicing and using bit position as sensitivity score. Given device budget per weight value is n=3 memristive devices (hence 3 crossbar columns per weight vector wⱼ). Required bit precision per weight value is m=4 bits. In the above example, one column is dedicated to first MSB (b₃), another column is allocated to second MSB (b₂) and one remaining column is allocated to all other bits (i.e., b₁b₀).

Other score functions may be designed based on the given algorithm and its parameters. It is also possible to use multiple score functions as ensembles to vote for the sensitivity scores of the bits. Moreover, the sensitivity score may be checked against a given threshold, where such threshold may be learned from the algorithm domain and its parameters. Also, the scores of multiple bits may be combined if one bit does not qualify alone for mapping to a crossbar column.

### Mapping Algorithm

As explained above, each column of the weights, wⱼ, may be mapped to n columns of memristive devices. Each weight may be represented by m bits, which should be assigned to n memristive device. As mentioned earlier, a parameter called device budget, n, may be defined as the number of memristive devices, which are used to represent an m-bit weight. There are two extremes for assigning the weights to the memristive devices:
1. If n=1, the whole m bits of each weight may be assigned to a single memristive device. This implies that the memristive device should have at least m-bit precision. In addition to these limitations, the performance of this approach degrades significantly by increasing the number of bits per weight (m), which is due to the sensitivity to the noise, very close conductance levels, and programming noise.
2. If n=m, each memristive device may represent one bit of the corresponding weight. However, this scenario is highly expensive especially for large values of m. Moreover, this approach is not flexible in case the number of bits per weight is changed.

However, if 1<n<m the bit assignment to the memristive devices is not straightforward. A well-known prior art solution is to perform homogeneous bit assignment. For example, in case of n=4 and m=8, two bits may be assigned to each device. But in this prior art approach the effect of different bit-positions on the performance, e.g., sensitivity level, is not considered. Also, it doesn't work for any desired combination of n and m.

In general, there are some challenges regarding mapping (bit assignment) the weights to the available memristive devices which have been described above.

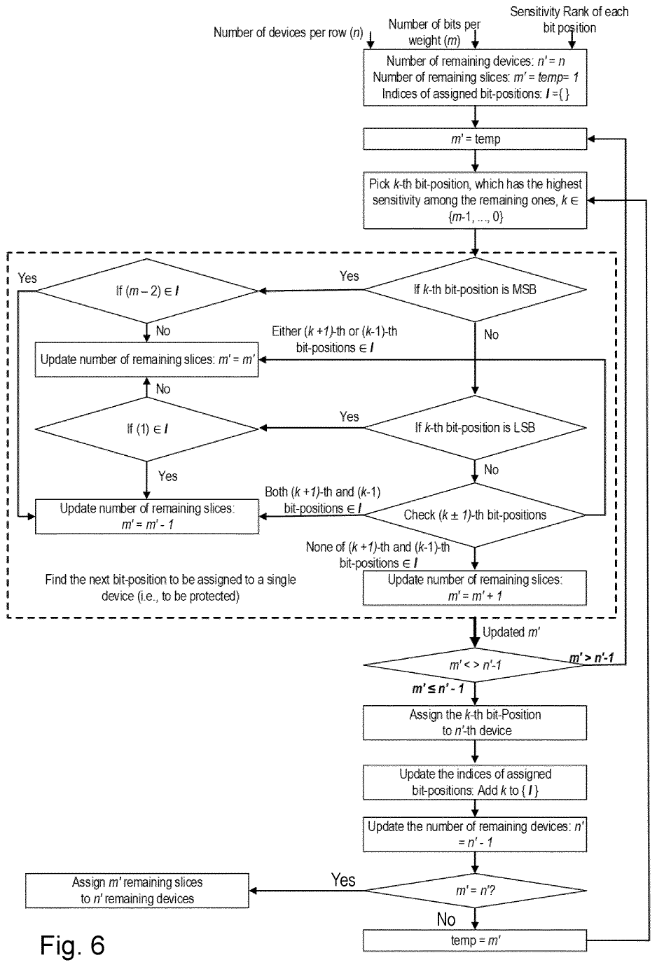

In order to address the above-mentioned challenges, embodiments herein comprises a mapping algorithm, which is shown in FIG. 6 and described below. Given an arbitrary device budget and weights, this algorithm finds an efficient mapping pattern of the weights to the memristive devices such that a maximum number of bits, which have the highest sensitivity level, are protected. The minimum number of protected bits may be equal to a=floor(n/2). However, depending on the relative position of the sensitive bits, the number of protected bit-positions may be increased up to n−1. This concept is elaborated with several examples below.

### Flowchart Description

As shown in FIG. 6, a mapping algorithm according to embodiments herein receives the device budget (n) and number of bits per weight (m). Sensitivity scores of different bit positions may be determined based on performance sensitivity of the applications with respect to each bit position. The mapping algorithm may for example receive a vector, which represents the sensitivity rank of all bit-positions, e.g., the k-th entry of this vector includes the sensitivity rank of bₖ.

Assignment may be based on a given device budget (n) and its relationship with the number of bits per parameter (m).

If n=1, assign the whole m bits of the parameter to a single memristive device.

If n=m, for each parameter bit assign a single memristive device.

If 1<n<m start assigning memristive devices to a bit of the parameter which has the highest sensitivity score.

The number of unassigned memristive devices (n′) may be compared to the number of remaining unassigned slices of bits of the parameter (m′). While the number of remaining unassigned memristive devices is larger than one, then assign the next bit parameter(s) with the highest sensitivity score among unassigned bits to a single memristive device among unassigned memristive devices. Whether one bit position or several bit positions will be assigned to the next device is determined by the position of the bit, a relative position of the most sensitive bits, and the number of remaining bit slices compared to the number of remaining devices. This procedure may be continued until one unassigned memristive device is left, which may be assigned to the remaining unassigned parameter bits.

The bit assignment of a column of weight matrix, wⱼ, may be done in an iterative manner. In each iteration the bit position with the highest sensitivity-level among the remaining bit-positions, which are not assigned to any memristive device yet, may be considered as a next candidate for assignment to a memristive device. Then, the algorithm may investigate if the candidate bit-position is eighter MSB or LSB, or if its adjacent bit-position is already assigned to a memristive device. In any of these cases it is assumed that the candidate bit-position will be assigned to a memristive device, and the number of remaining slices, m′, is calculated accordingly. If the number of remaining memristive devices is enough for the remaining slices, e.g., if m′<n′−1, the current bit position is assigned to a memristive device, the number of remaining memristive devices, n′=n′−1, is calculated and the next iteration of the algorithm is executed for the next candidate bit-position. Otherwise, no memristive device is assigned to the current candidate bit position and the algorithm selects the next bit position with highest sensitivity-level and performs similar steps for that bit-position. Moreover, in this case, since no bit assignment is done, the value of m′ will not be updated and its old value is used instead, which may be stored in a parameter “temp”. Similarly the value of n′ is not changed.

The above procedure is repeated until n′=m′, where the remaining slices of the weights may be assigned to the remaining memristive devices. As a result, the maximum number of sensitive bits will be assigned to separate memristive devices, in other words protected, while the device budget is efficiently utilized, e.g., 100% utilized.

### Example Scenarios of Mapping Algorithm

In order to clarify the mapping algorithm of embodiments herein, several example scenarios will be described for different number of bits per weight and number of devices per weight as well as different positions for sensitive bits.

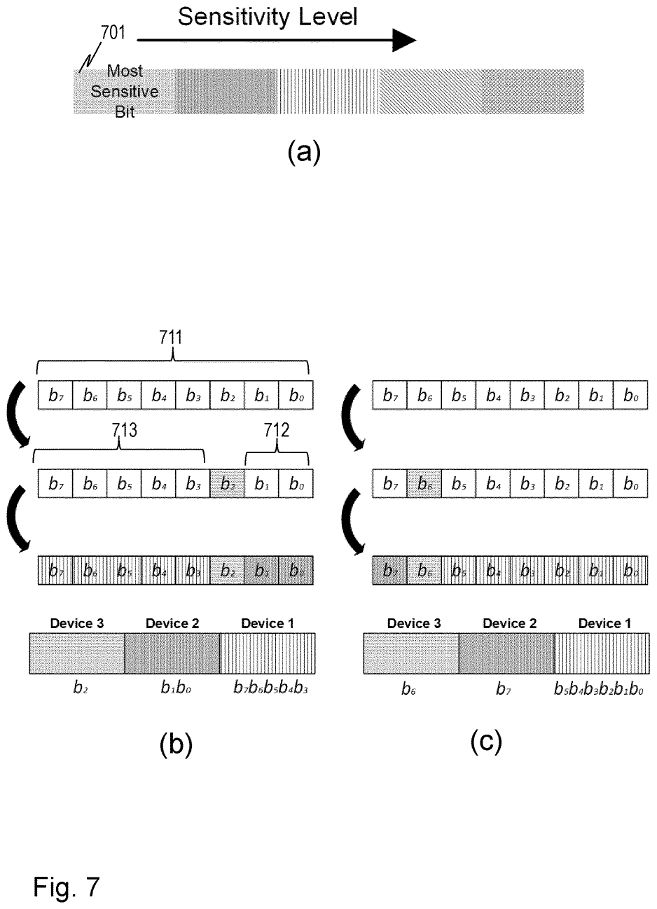

FIG. 7(a) shows a coding of the memristive devices such that the leftmost one represents the highest sensitive bit-position. Each of FIG. 7(b) and FIG. 7(c) illustrates a step-by-step mapping of an arbitrary 8-bit weight (m=8) to n memristive devices, following the algorithm of FIG. 6. Then, the actual pattern of the bits on the programmed devices is shown in the last row of each of FIG. 7(b) and FIG. 7(c).

The electronic device 300 may select a candidate bit to be assigned. The electronic device 300 may select a bit with a highest assigning priority as a candidate bit to be assigned out of unassigned bits which have not been selected as the candidate bit. For example, in FIG. 7(b) the electronic device 300 selects a bit b₂ which is the third bit from right to left for assignment to the first memristive device from the left, Device 3, in the second row (the bit is marked with the pattern of the device).

The electronic device 300 may obtain a number of remaining unassigned slices of consecutive bits. A slice of bits is a number of consecutive bits. For example, in FIG. 7(b), in the first iteration, represented by the top row of bits, there is a first remaining unassigned slice of consecutive bits 711. In the second iteration, represented by the second row of bits, there are two remaining unassigned slices of consecutive bits comprising a second remaining unassigned slice of consecutive bits 712 (b₃-b₇) and a third remaining unassigned slice of consecutive bits 713 (b₁b₀).

The electronic device 300 may obtain a number of remaining unassigned memristive devices. For example, in FIG. 7(b), in the first iteration, represented by the top row of bits, there are three remaining unassigned memristive devices: a first unassigned memristive device Device 1, a second unassigned memristive device Device 2 and a third unassigned memristive device Device 3. The memristive devices Device 1, Device 2, Device 3 of FIG. 7(a) and FIG. 7(b) correspond to the memristive devices of FIG. 3, such as the memristive devices 311, 321.

In the second iteration, represented by the second row of bits, there are two remaining unassigned memristive devices, namely the second unassigned memristive device Device 2 and the first unassigned memristive device Device 1.

Note that, although the assigned bits to the memristive devices are not in natural order in the depicted figures, the final value of represented number will be obtained correctly at the end. This point may be considered in a reconfigurable shift and add tree, and therefore it doesn't matter which bit position is assigned to which device. However, the reordering of the bit positions may be done by a simple index mapping, if for any reason the natural order is needed. For example, in FIG. 7(b), after finding a mapping pattern and before programming the devices it is possible to reorder the three slices such that always the slice, which includes MSB is programmed to the leftmost device (i.e., b₇b₆b₅b₄b₃ is programmed to Device 3), the one which includes the LSB is programmed to the rightmost device (i.e., b₁b₀ is programmed to Device 1), and the middle slice is programmed to the middle device (i.e., b₂ is programmed to Device 2).

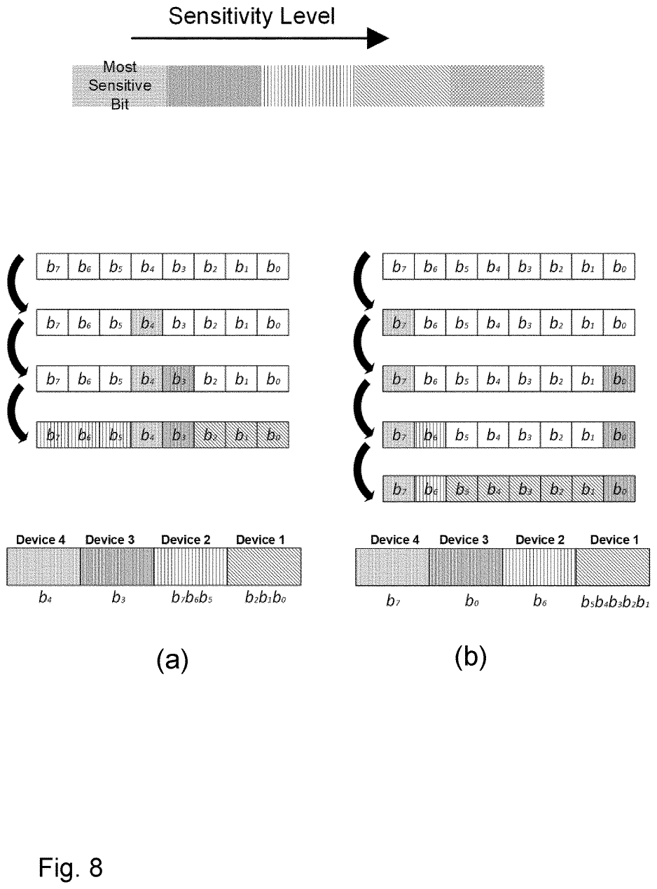

Another example for m=8 bits per weight and n=4 devices per weight is shown in FIG. 8(a) and FIG. 8(b). In this example, two bits and three bits may be protected with the same hardware in FIG. 8(a) and of FIG. 8(b), respectively.

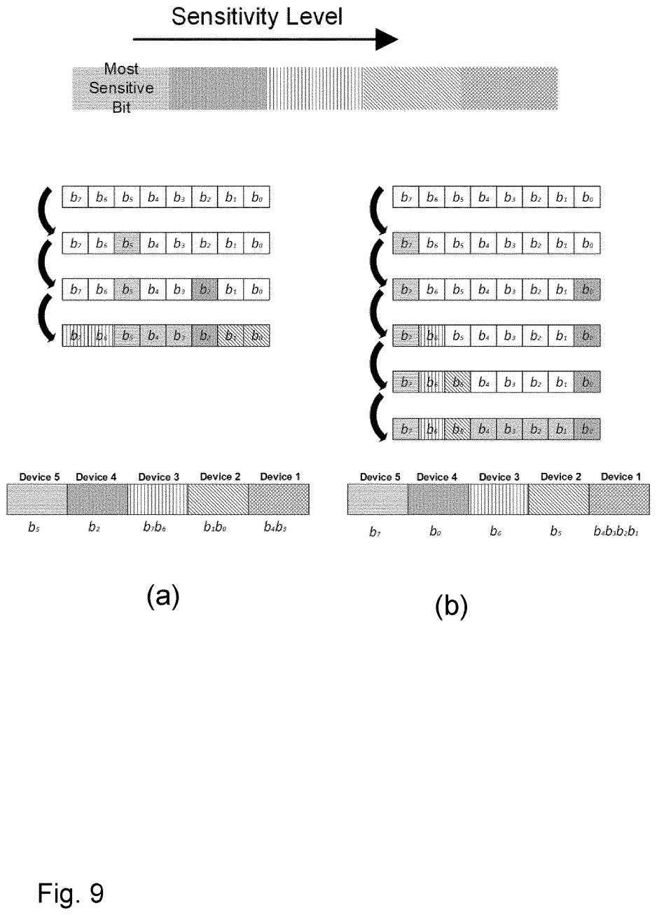

In each scenario the values of m and n are fixed. However, the number of bits which may be protected varies between floor(n/2) to (n−1) bit positions. This depends on the relative position of the bits with high sensitivity in the set of weights in wⱼ. For example, in FIG. 7(b) the second bit is adjacent the MSB and it may therefore be protected as well since there is only one remaining slice which need to be assigned to the remaining device. A second bit adjacent to the LSB would have a similar result. In another example, in FIG. 9(a) and FIG. 9(b) where n=5 devices are used to represent the weights, two and four bits may be protected, respectively with the same hardware. However, the pattern and number of protected bits may be changed if the weights are changed, and the crossbar array is reprogrammed accordingly.

In embodiments herein a slice of bits includes less than m bits. Thus, by assigning a slice of bits to a single memristive device, the corresponding bits will be protected better compared with the case in which the whole m bits are assigned to a single memristive device. Further, in embodiments herein a number of bits are fully protected by assigning them to separate single memristive devices. In addition to this, the remaining bits are partially protected since less than m bits are assigned to a single memristive device compared to prior art schemes in which all m bits are assigned to a single memristive device. A secondary advantage of the proposed scheme is that the other slices of the weights will be more reliable compared to the case that the whole weight is assigned to a single device. In worst case, m−(floor(n/2)) bits are assigned to one memristive device instead of assigning m bits to one memristive device.

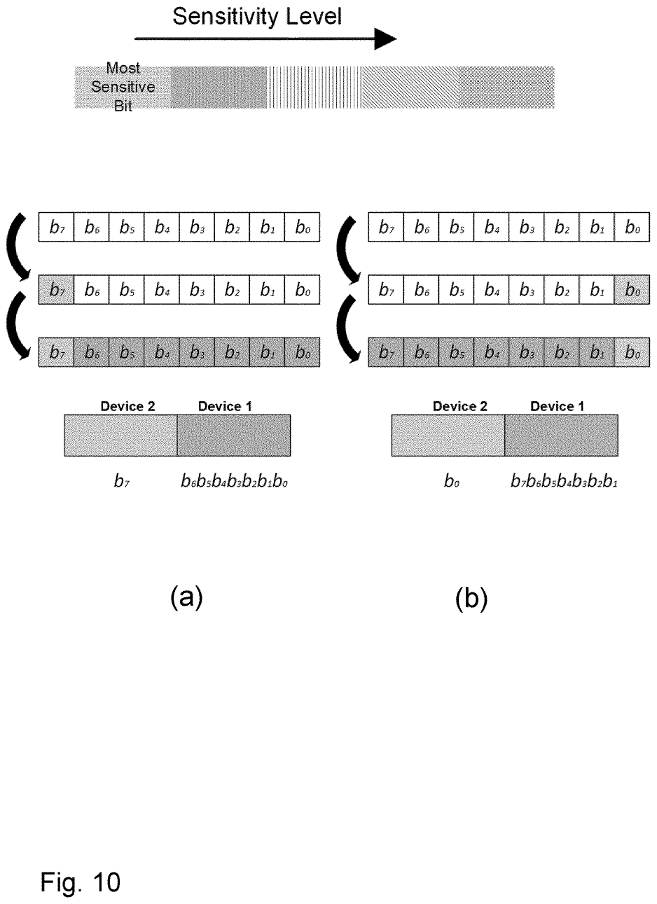

Finally, two special cases are shown in FIG. 10, where only two memristive devices are available to represent the weights. In such cases either MSB or LSB may be protected as shown in FIGS. 10(a) and 10(b), respectively, if LSB or MSB is one of the highly sensitive bits, or at least is not the bit with the lowest assignment priority.

### EXAMPLE USE CASES

### Computer Vision: Example 1

In this simple example there is a decision parameter w with three bits b₂b₁b₀. This decision parameter is intended for distinguishing between images that contain a dog vs those containing a cat. The images include context information (in the background of the image) such as “cat at home”, “dog in the garden”, “cat in the bus” etc. Bit b₀ is used to distinguish dog and cat (b₀=0 (cat), b₀=1 (dog)) and the remaining two bits are used to represent context information (e.g. b₂b₁=00 (home), b₂b₁=01 (office), b₂b₁=10 (bus), b₂b₁=11 (garden)). This results in the following values of w:

$${b}_{2} {b}_{1} {b}_{0} = 000 ( cat at home )$$

$${b}_{2} {b}_{1} {b}_{0} = 001 ( dog at home )$$

$${b}_{2} {b}_{1} {b}_{0} = 010 ( cat at office )$$

$${b}_{2} {b}_{1} {b}_{0} = 011 ( dog at office )$$

$${b}_{2} {b}_{1} {b}_{0} = 100 ( cat in bus )$$

$${b}_{2} {b}_{1} {b}_{0} = 101 ( dog in bus )$$

$${b}_{2} {b}_{1} {b}_{0} = 110 ( cat in garden )$$

$${b}_{2} {b}_{1} {b}_{0} = 111 ( dog in garden )$$

It may be mostly interesting to distinguish images based on whether the image contains cat or dog, and distinguishing the context is of less interest (e.g. only to help distinguish better between dog and cat images). In other words, the application is more sensitive to a distinction of cat vs dog than to the context where cat or dog are located. Having this in mind, if device budget is 2, one device may be assigned to b₀ (high sensitivity bit) and another device to be shared between b₂b₁ (low sensitivity bit). Note that this example clearly shows that the high sensitivity bit is not always MSB.

### Computer Vision: Example 2

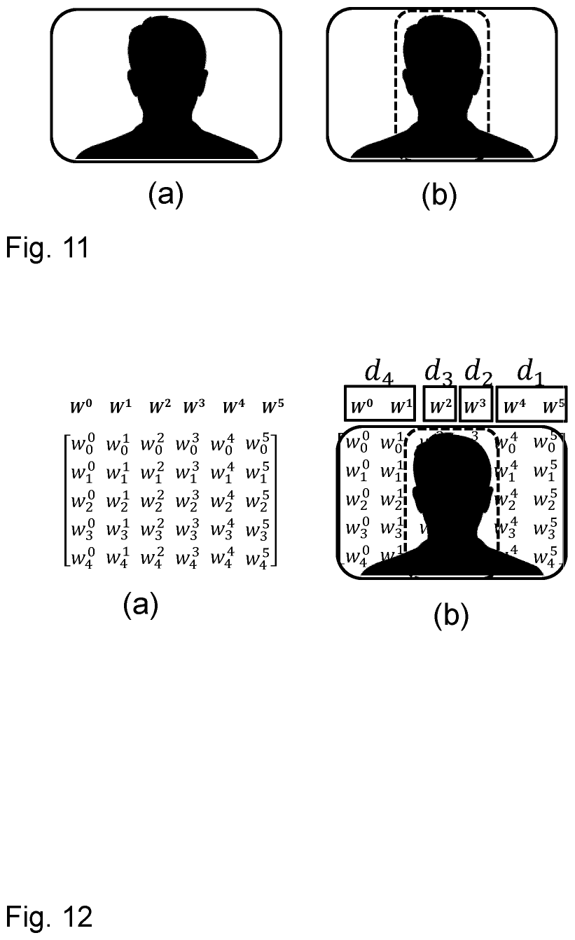

Suppose it is desired to detect faces from selfie photos captured by a camera. An original photo is depicted in FIG. 11 (a). Assume that, based on insights acquired from an application domain, it is realized that a face is often situated in the middle of the photo. This is illustrated by a dashed inner rectangle in FIG. 11 (b).

Also suppose that the algorithm (such as a filter) is intended to detect the face in the photo or at least to extract some features of the face to be used by another face detection/recognition algorithm. Parameters of such an algorithm are depicted in FIG. 12 (a). Each row of the filter is assumed to be a binary vector. The vector may also be composed of decimal values, but for simplicity binary numbers are assumed here. Mapping the filter to the photo—see FIG. 12(b)—reveals that column vectors W² and W³ have the largest overlap with the region in the center of photo. The device budget is 4 in this example. Since the center region contains the most useful information for detecting the face compared to other regions corresponding to image background, embodiments herein may exclusively allocate one device per weight elements in W, one device per weight elements in W³. Then, embodiments herein may allocate only one device per pair of weight elements in [W⁰, W¹] and [W⁴, W⁶].

A key step in the processing chain of wireless communication systems is to map the received noisy signal to one of the nearest constellation points. This means that if the value of real/imaginary part of the received signal slightly changes, it may be mapped to another constellation point, which increases the error rate of the system. This is more important when the received signal is very close to the middle line of two neighbor constellation points.

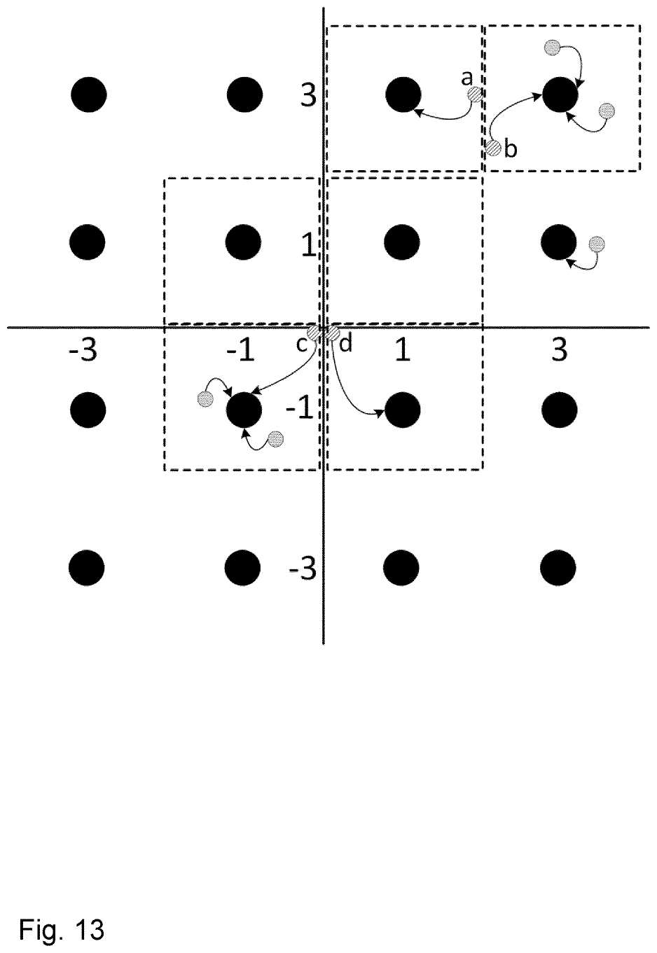

FIG. 13 shows a 16 QAM constellation, where the constellation points are shown with black wholly filled dots and the received signals are shown by dots filled with different patterns. Each dashed square specifies a region, in which any received signal in that area will be mapped to the constellation point within that square, as shown by the arrows in FIG. 13. There are many cases for which a value of a real/imaginary part of the received signal is close to the border of dashed squares. For example, the dots filled with lines in FIG. 13. In such cases, the mapping to the correct constellation point is challenging and some specific bit positions of the real/imaginary part become very sensitive.

In an example the real/imaginary part of the received signals is represented by 8 bits. For example, in FIG. 13, the real part of received signals “a” and “b”, which are very close together, are 1.93 (00011111 in binary) and 2.12 (00100010 in binary), respectively. It can be seen that a bit flipping in the third and fourth bit positions (from the left) changes the symbol mapping such that “a” is mapped to the constellation point 1+3j while “b” is mapped to 3+3j. But, any change in the next four bits will not affect the mapping. For example, if the real part of “b” is changed from 00100010 to 00100011 or 00101111, it is still mapped to the same constellation point (3+3j) as before.

There are even more sensitive cases like the received signals “c” and “d” in FIG. 12, which both real and imaginary parts are very close.

As a result, in this application, some specific bit positions are more sensitive than the others, which may be protected by embodiments herein employing heterogeneous bit-slicing.

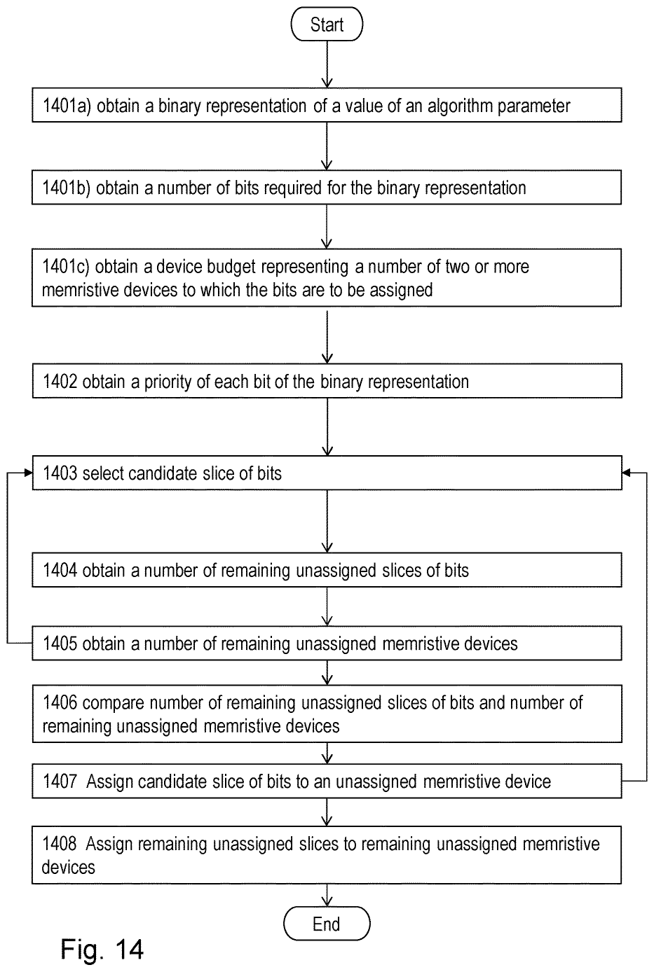

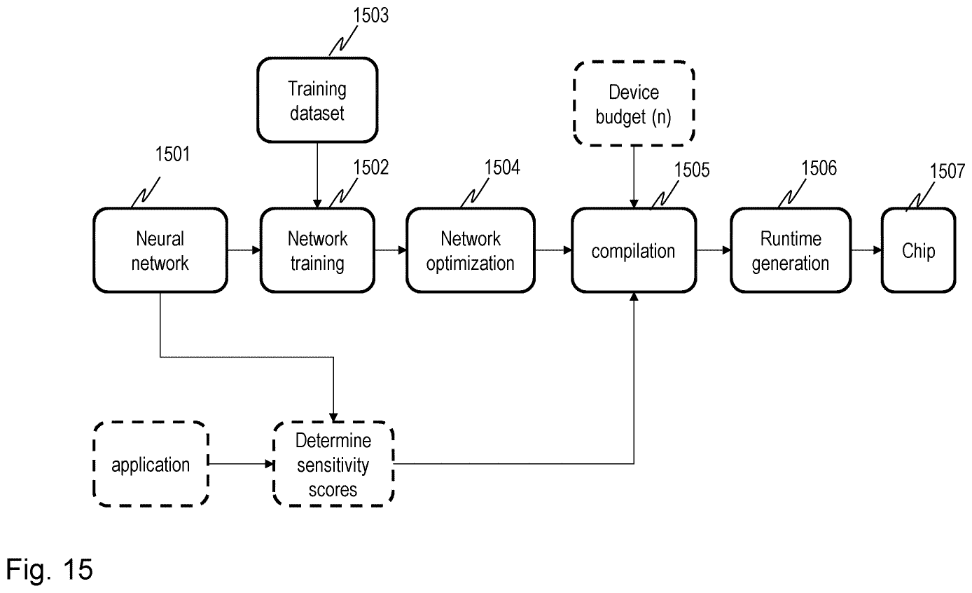

Exemplifying methods according to embodiments herein will now be described with reference to a flow chart in FIG. 14. The flow chart illustrates a method of heterogeneous bit slicing for allocating a plurality of memristive devices 311, 321 to store bits, performed by the electronic device 300. More specifically, the flow chart illustrates a method performed by the electronic device 300 for assigning a number of bits of a binary representation of a value to two or more memristive devices 311, 321 of the crossbar array 301 comprising the plurality of memristive devices 311, 321. The number of bits to be assigned is larger than a number of the two or more memristive devices 311, 321. That is, an amount of bits is larger than an amount of the two or more memristive devices 311, 321. For example, the number of bits may be four, while the number of the two or more memristive devices 311, 321 may be three.

In embodiments herein the bits of the binary representation of the value may be assigned in groups called slices. Each slice comprises one or more consecutive unassigned bits. Each assigned slice comprises less than all the bits to be assigned.

The method actions of FIG. 14 are not necessarily performed in the described order but may be performed in any suitable order.

### Action 1401

The electronic device 300 may obtain input parameters. For example, the electronic device 300 may obtain the binary representation of the value. The electronic device 300 may further obtain a number of bits required for the binary representation and a device budget representing the number of two or more memristive devices 311, 321 to which the bits are to be assigned.

### Action 1402

The electronic device 300 obtains an assigning priority of each bit of the binary representation of the value. The assigning priority may change from case to case.

The assigning priority of each bit may be based on a performance sensitivity of an algorithm with respect to the bit. In some embodiments herein the assigning priority is based on any one or more of: a bit toggle rate or a bit position.

A bit which is not the MSB nor the LSB may have a highest assigning priority.

Obtaining the assignment priority may be performed in a software module and that modules may run in the electronic device 300 or run outside the electronic device 300.

### Action 1403

The electronic device 300 may select a candidate bit to be assigned. This was described above in relation to FIG. 6.

The electronic device 300 may select a bit b₂ with a highest assigning priority 701 as a candidate bit to be assigned out of unassigned bits b₇-b₀ which have not been selected as the candidate bit.

### Action 1404

The electronic device 300 may obtain the number of remaining unassigned slices of consecutive bits. As mentioned above, in FIG. 7(b), in the first iteration, represented by the top row of bits, there is one remaining unassigned slice of consecutive bits, the first slice 711. In the second iteration, represented by the second row of bits, there are two remaining unassigned slices of consecutive bits: the second slice 712 (b₃-b₇) and the third slice 713 (b₁b₀).

### Action 1405

The electronic device 300 may obtain a number of remaining unassigned memristive devices. For example, in FIG. 7(b), in the first iteration, represented by the top row of bits, there are three remaining unassigned memristive devices. In the second iteration, represented by the second row of bits, there are two remaining unassigned memristive devices, namely the second remaining unassigned memristive device Device 2 and the first remaining unassigned memristive device Device 1.

### Action 1406

The electronic device 300 may compare the number of remaining unassigned slices 711, 712, 713 of consecutive bits and the number of remaining unassigned memristive devices Device 1, Device 2, Device 3.

### Action 1407

The method for assigning the bits may be divided into two parts. In a first part bits with high assignment priority are assigned exclusively to a respective unassigned memristive device in order of assignment priority of the bits. When the number of remaining unassigned memristive devices 311, 321 after the assignment of the previously unassigned bit equals the number of remaining unassigned slices of the one or more consecutive unassigned bits after the assignment of the previously unassigned bit, then the second part comprises assigning the remaining unassigned memristive devices to the remaining unassigned slices of the one or more consecutive unassigned bits. The second part will be further described below in action 1408. For both the first part and the second part of the method, a slice of one or more consecutive bits is assigned to a respective memristive device.

For an unassigned memristive device 311, 321 of the two or more memristive devices 311, 321, the electronic device 300 assigns the unassigned bit b₂ of the number of bits to the unassigned memristive device 311, 321 based on: the assigning priority 701 of the unassigned bit b₂, the number of remaining unassigned memristive devices 311, 321 after the assignment of the unassigned bit b₂ and the number of remaining unassigned slices 712, 713 of one or more consecutive unassigned bits after the assignment of the unassigned bit b₂.

Assigning of the unassigned bit may comprises updating the number of remaining unassigned slices of the one or more consecutive unassigned bits based on the selected candidate bit to be assigned.

Assigning of the unassigned bit may further comprises updating the number of remaining unassigned memristive devices by subtracting one.

When the updated number of remaining unassigned slices is less or equal than the updated number of remaining unassigned memristive devices, assigning of the unassigned bit may comprise assigning the selected candidate bit to the unassigned memristive device 311, 321.

The assigning may be performed iteratively as illustrated in FIGS. 6-9.

In some embodiments assigning the unassigned bit comprises assigning a first memristive device 311 of the two or more memristive devices 311, 321 exclusively to a single first bit b₂ with the highest assigning priority 701 of the bits. For example, the electronic device 300 may assign the unassigned bit b₂ by assigning the first memristive device 311 of the two or more memristive devices 311, 321 exclusively to the single first bit b₂ with the highest assigning priority 701 of the bits. See also the examples above of FIGS. 7-9. At least one bit may be exclusively assigned to a memristive device.

In some embodiments at least two bits b₆, b₇ of the number of bits for the binary representation of the value are exclusively assigned to a respective memristive device 311, 321 of the two or more memristive devices 311, 321.

When a number of the two or more memristive devices 311, 321 is given by an integer n and then a number of bits that are exclusively assigned to a respective memristive device of the plurality of memristive devices 311, 321 is between floor(n/2) and n−1.

### Action 1408

The method may further comprise, in response to the number of remaining unassigned memristive devices equals the number of remaining unassigned slices of the one or more consecutive unassigned bits, to assign the remaining unassigned memristive devices to the remaining unassigned slices of the one or more consecutive unassigned bits. That is, each remaining unassigned memristive device is assigned to a respective remaining unassigned slice. This is for example related to the assignment of the second slice 712 to the second memristive device Device 2 and to the assignment of the third slice 713 to the third memristive device Device 3 in FIG. 7(b).

### Implementation and Deployment Workflow

FIG. 15 illustrates a workflow for implementation and deployment of algorithms on hardware accelerators, exemplified by a neural network model to be accelerated on a chip 1507, such as a mixed-signal chip. The solid boxes show modules which in part may be used in existing products. The hatched boxes are added for enabling embodiments herein. Embodiments herein for heterogeneous bit slicing may be performed in a compilation module 1505. A neural network 1501 may be fed to a network training module 1502 to train the network using a dataset 1503. The output trained network may further be optimized, e.g. by quantization to lower bit precision and network pruning, and possibly re-trained if needed in a network optimization module 1504. Output weight parameters jointly with sensitivity scores, determined from the application domain, and device budget may be fed to the compilation module 1505. The compilation module 1505 may also have information about the hardware of the chip 1507, e.g. a number and capacity of arrays, memory, peripheries etc. The compilation module 1505 creates a mapping of the parameters to the crossbar arrays in the chip 1507 based on embodiments disclosed herein. Finally, a runtime generation module 1506 may create a runtime binary to be executed on the chip.

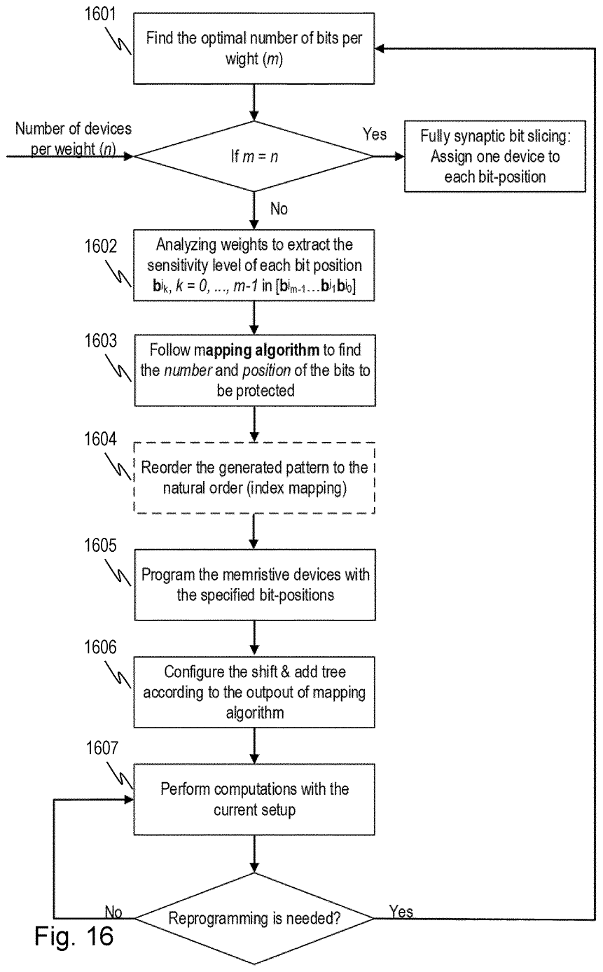

FIG. 16 illustrates a flowchart of some embodiments disclosed herein for heterogenous synaptic bit-slicing, which will be briefly explained below.

### Action 1601

First, an optimal number of bits (m) to represent weights in wⱼ may be determined. This may be done by means of simulation to find a best tradeoff between performance and hardware cost.

### Action 1602

Then, a whole set of weights in the vector wⱼ are analyzed to find a sensitivity level of each bit position, i.e., [b^{j}ₘ₋₁b^{j}ₘ₋₂ . . . b^{j}₁b^{j}₀]. This may be done based on a corresponding score function, as described above.

### Action 1603

In a next action, a mapping algorithm may be executed to find a maximum number of bit-positions that may be protected using the available memristive devices.

### Action 1604

The generated pattern may be reordered, e.g., to natural order.

### Action 1605

The memristive devices may be programmed based on a bit-assignment pattern, generated by the mapping algorithm.

### Action 1606

Moreover, the shift and adder modules 316 may be configured according to the output of the mapping algorithm.

### Action 1607

Computations may be performed with the memristive devices to generate the final result of vector matrix multiplication.

The current setup may remain fixed until the weights are changed, and a reprogramming is requested. In that case, the above actions may be repeated. Thus, the bit-assignment pattern of the updated weights as well as the number of protected bit-positions may be changed.

As shown in the flowchart, there is a special case where number of bits per weights is equal to the device budget, m=n. In this case, there is no need to analyze the bit positions (i.e., no need to define the score function) since all the bits may be protected using a one-by-one mapping, i.e., direct mapping.

The dashed rectangle of action 1604 in the flowchart is an optional step, which corresponds to the reordering of the bit positions in case natural-order representation is needed. This concept was explained above with an example.

Embodiments herein discloses a heterogeneous bit slicing for assigning memristive devices to algorithm parameters, such as weights of a neural network. In embodiments herein, given the binary representation of the algorithm parameter and given a certain device budget per parameter, memristive devices may be exclusively assigned to high sensitivity bits while the low sensitivity bits tend to share the same memristive device to meet the device budget constraint.

Embodiments herein may relate a bit slicing and device allocation problem to characteristics from the application domain through sensitivity scores assigned to individual bits in the binary representation of the parameters. This results in generalizing the notion of bit importance beyond position-based scoring of bits. In other words, any bit, regardless of its position in the binary representation, may have a high sensitivity score, e.g., determined from the application domain.

Embodiments herein further disclose a mapping technique to map parameters of an algorithm onto the analog crossbar array, where the mapping technique employs heterogeneous bit slicing which may be based on sensitivity score values assigned to individual bits of the algorithm parameter.

The proposed mapping technique finds the maximum number of bits in the binary representation of the parameter to be protected depending on the relative positions of the sensitive bits. In this context a “protected bit” may mean a bit, presumably with a high sensitivity score, which is exclusively programmed on a dedicated memristive device. Similarly, the proposed mapping algorithm always guarantees a minimum number of protected bits, which is floor(n/2).

By taking the device budget constraint and the number of bits into account for the bit slicing and the mapping of the bits to the memristive devices the assigning is flexibly optimized for the actual bits and memristive devices used.

Moreover, the mapping algorithm addresses the most general case where device budget is less than or equal to the number of required bit precision for the algorithm parameter.

Some additional advantages of heterogenous bit-slicing vs. homogeneous solution include:
a) Potential improvement of algorithm accuracy through the allocation of memristive devices based on bit sensitivity scores of the algorithm parameters. This improvement is obtained due to two factors: 1) more separation between consecutive conductance levels may be achieved during the programming of important bits, hence more robustness to noise is obtained in the algorithm side, 2) quantization error due to ADC is reduced in the columns of the crossbar array with fewer programmed bits in each memristive device.
b) The improvement achieved comes with little to no additional cost. More specifically, no specific hardware is needed to support heterogeneous bit-slicing. Calculation of scores and allocation of crossbar columns may be performed in software domain.
c) The flexible heterogeneous bit-slicing method may be applied to existing and emerging memristive devices with any supported bit precision and to mapping of algorithm parameters with any required bit precision.
d) Embodiments herein are flexible in terms of the number of bits to be protected as well as their positions. As a result, for a given crossbar array this scheme may fully utilize the available hardware while improving the overall performance.
e) Embodiments herein are independent of the input encoding format, i.e., they may receive bit-serial inputs or receive the whole input word at once.
f) Embodiments herein support any size of algorithm parameters and any crossbar array size.

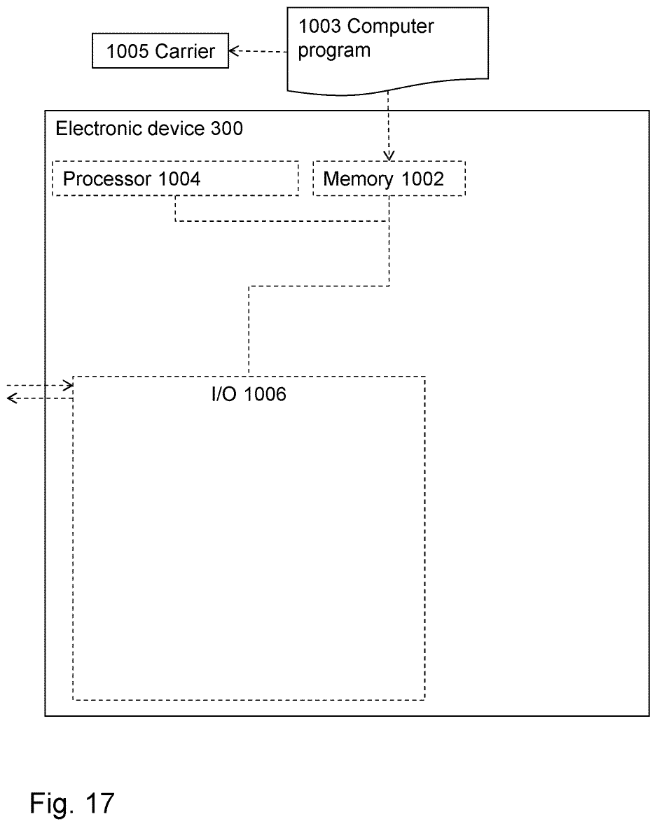

FIG. 17 shows a further embodiment of the electronic device 300. The electronic device 300 may be configured to perform the method actions of FIG. 14. In particular, the electronic device 300 is configured to assign the number of bits of the binary representation of the value to the two or more memristive devices 311, 321 of the crossbar array 301. The electronic device 300 is further configured to obtain the assigning priority of each bit of the binary representation of the value.

For an unassigned memristive device 311, 321 of the two or more memristive devices 311, 321 the electronic device 300 is further configured to assign an unassigned bit b2 of the number of bits to the unassigned memristive device 311, 321 based on the assigning priority of the unassigned bit, a number of remaining unassigned memristive devices 311, 321 after the assignment of the unassigned bit and a number of remaining unassigned slices 712, 713 of one or more consecutive unassigned bits b7b3, b1b0 after the assignment of the unassigned bit b2.

In some embodiments the electronic device 300 is further configured to assign the unassigned bit by being configured to:
select a bit with a highest assigning priority as a candidate bit to be assigned out of unassigned bits which have not previously been selected as the candidate bit;
   update the number of remaining unassigned slices of the one or more consecutive unassigned bits based on the selected candidate bit to be assigned;
   update the number of remaining unassigned memristive devices 311, 321 by subtracting one from the number of remaining unassigned memristive devices 211, 221; and
   assign the selected candidate bit to the unassigned memristive device 311, 321 if the updated number of remaining unassigned slices is less or equal than the updated number of remaining unassigned memristive devices.

In response to the number of remaining unassigned memristive devices equals the number of remaining unassigned slices of the one or more consecutive unassigned bits, electronic device 300 may be further configured to assign the remaining unassigned memristive devices to the remaining unassigned slices of the one or more consecutive unassigned bits.

The electronic device 300 may be configured to perform the assigning iteratively.

In some embodiments the electronic device 300 is configured to assign the unassigned bit by being configured the first memristive device 311 of the two or more memristive devices 311, 321 exclusively to the single first bit with the highest assigning priority of the bits.

The electronic device 300 may be configured to assign between floor n/2 and n−1 exclusively assigned number of bits to the respective memristive device of the plurality of memristive devices 311, 321.

The electronic device 300 may comprise an input and output interface, IF, 1006. The input and output interface may comprise a wireless receiver (not shown) and a wireless transmitter (not shown).

The embodiments herein may be implemented through a processor or one or more processors, such as the processor 1004, of a processing circuitry in the electronic device 300 depicted in FIG. 17 together with computer program code for performing the functions and actions of the embodiments herein. The program code mentioned above may also be provided as a computer program product, for instance in the form of a data carrier carrying computer program code for performing the embodiments herein when being loaded into the electronic device 300. One such carrier may be in the form of a CD ROM disc. It is however feasible with other data carriers such as a memory stick. The computer program code may furthermore be provided as pure program code on a server and downloaded to the electronic device 300.

The electronic device 300 may further comprise a memory 1002 comprising one or more memory units. The memory comprises instructions executable by the processor in the electronic device 300.

In some embodiments, a computer program 1003 comprises instructions, which when executed by at least one processor, such as the processor 1004, of the electronic device 300, cause the at least one processor of the electronic device 300 to perform the actions above. The computer program 1003 may be loaded into the memory 1002.

In some embodiments, a carrier 1005 comprises the computer program, wherein the carrier is one of an electronic signal, an optical signal, an electromagnetic signal, a magnetic signal, an electric signal, a radio signal, a microwave signal, or a computer-readable storage medium.

Those skilled in the art will also appreciate that the units described above may refer to a combination of analog and digital circuits, and/or one or more processors configured with software and/or firmware, e.g. stored in the electronic device 300, that when executed by the respective one or more processors such as the processors described above. One or more of these processors, as well as the other digital hardware, may be included in a single Application-Specific Integrated Circuitry ASIC), or several processors and various digital hardware may be distributed among several separate components, whether individually packaged or assembled into a system-on-a-chip (SoC).

When using the word “comprise” or “comprising” it shall be interpreted as non-limiting, i.e. meaning “consist at least of”.

The embodiments herein are not limited to the above described preferred embodiments. Various alternatives, modifications and equivalents may be used.

1.-14. (canceled)

15. A method for assigning a first number of bits of a binary representation of a value to a second number of memristive devices within a crossbar array, wherein the second number is two or more and the first number is larger than the second number, wherein the method is performed by an electronic device and comprises:
obtaining an assigning priority of each bit of the binary representation of the value; and
for an unassigned memristive device of the second number of memristive devices within the crossbar array, assigning an unassigned bit (b₂) of the first number of bits to the unassigned memristive device based on the following:
an assigning priority of the unassigned bit,
a third number of remaining unassigned memristive devices after the assignment of the unassigned bit, and
a fourth number of unassigned slices of one or more consecutive unassigned bits (b₇b₃, b₁b₀) remaining after assignment of the unassigned bit (b₂),
wherein assigning the unassigned bit (b₂) of the first number of bits to the unassigned memristive device is performed iteratively and comprises:
selecting an unassigned bit having a highest assigning priority as a candidate bit, from among unassigned bits which have not previously been selected as a candidate bit;
updating the fourth number of remaining unassigned slices based on the selected candidate bit to be assigned;
updating the third number of remaining unassigned memristive devices by subtracting one from the third number; and
when the updated fourth number is less than or equal to the updated third number, assigning the selected candidate bit to the unassigned memristive device;
wherein the method further comprises, in response to the third number of remaining unassigned memristive devices being equal to the fourth number of remaining unassigned slices, assigning the remaining unassigned memristive devices to the remaining unassigned slices.

16. The method according to claim 15, wherein the assigning priority of each bit is based on an algorithm performance sensitivity with respect to the bit.

17. The method according to claim 15, wherein the assigning priority of each bit is based on one or more of the following for the bit: a bit toggle rate, and a bit position.

18. The method according to claim 15, wherein the highest assigning priority is associated with one of the bits that is neither the Most Significant Bit (MSB) nor the Least Significant Bit (LSB).

19. The method according to claim 15, wherein assigning the unassigned bit (b₂) of the first number of bits to the unassigned memristive device further comprises assigning a first bit (b₂), having highest assigning priority among the first number of bits, exclusively to a first one of the second number of memristive devices.

20. The method according to claim 15, wherein at least two bits (b₆, b₇) of the binary representation of the value are exclusively assigned to respective at least two memristive devices of the crossbar array.

21. The method according to claim 15, wherein:
the second number of memristive devices is an integer n, and
a number of bits, of the binary representation of the value, that are exclusively assigned to respective memristive devices of the crossbar array is between floor (n/2) and n−1.

22. An electronic device configured to assign a first number of bits of a binary representation of a value to a second number of memristive devices within a crossbar array, wherein the second number is two or more and the first number is larger than the second number, wherein the electronic device comprises a processing circuitry configured to:
obtain an assigning priority of each bit of the binary representation of the value; and
for an unassigned memristive device of the second number of memristive devices within the crossbar array, assign an unassigned bit (b₂) of the first number of bits to the unassigned memristive device based on the following:
an assigning priority of the unassigned bit,
a third number of remaining unassigned memristive devices after the assignment of the unassigned bit, and
a fourth number of unassigned slices of one or more consecutive unassigned bits (b₇b₃, b₁b₀) remaining after assignment of the unassigned bit (b₂),
wherein the processing circuitry is configured to iteratively assign the unassigned bit (b₂) of the first number of bits to the unassigned memristive device based on the following operations:
select an unassigned bit having a highest assigning priority as a candidate bit, from among unassigned bits which have not previously been selected as a candidate bit;
update the fourth number of remaining unassigned slices based on the selected candidate bit to be assigned;
update the third number of remaining unassigned memristive devices by subtracting one from the third number; and
when the updated fourth number is less than or equal to the updated third number, assign the selected candidate bit to the unassigned memristive device;
wherein the processing circuitry is further configured to, in response to the third number of remaining unassigned memristive devices being equal to the fourth number of remaining unassigned slices, assign the remaining unassigned memristive devices to the remaining unassigned slices.

23. The electronic device according to claim 22, wherein the assigning priority of each bit is based on an algorithm performance sensitivity with respect to the bit.

24. The electronic device according to claim 22, wherein the assigning priority of each bit is based on one or more of the following for the bit: a bit toggle rate, and a bit position.

25. The electronic device according to claim 22, wherein the highest assigning priority is associated with one of the bits that is neither the Most Significant Bit (MSB) nor the Least Significant Bit (LSB).

26. The electronic device according to claim 22, wherein the processing circuitry is configured to assign the unassigned bit (b₂) of the first number of bits to the unassigned memristive device further based on assigning a first bit (b₂), having highest assigning priority among the first number of bits, exclusively to a first one of the second number of memristive devices.

27. The electronic device according to claim 22, wherein at least two bits (b₆, b₇) of the binary representation of the value are exclusively assigned to respective at least two memristive devices of the crossbar array.

28. The electronic device according to claim 22, wherein:
the second number of memristive devices is an integer n, and
a number of bits, of the binary representation of the value, that are exclusively assigned to respective memristive devices of the crossbar array is between floor (n/2) and n−1.

29. A non-transitory, computer-readable medium storing computer program code that, when executed on a processor of an electronic device, causes the electronic device to perform the method according to claim 15.
